(19) United States
(12) Patent Application Publication
(10) Pub. No.: US 2016/0123905 A1
(43) Pub. Date: May 5, 2016

(54) Inspection of inconsistencies in and on semiconductor devices and structures

(71) Applicant: MACRONIX INTERNATIONAL CO., LTD., Hsinchu (TW)

(72) Inventors: Hsiang-Chou Liao, Taipei City (TW); Tuung Luoh, Taipei City (TW); Ling-Wuu Yang, Hsinchu City (TW); Tahone Yang, Miaoli County (TW); Kuang-Chao Chen, Taipei City (TW)

(21) Appl. No.: 14/532,773

(22) Filed: Nov. 4, 2014

(51) Int. Cl. G01N 23/203; H01J 37/252; H01L 21/66

(52) U.S. Cl. CPC G01N 23/203; H01L 22/12; H01J 37/252

(57) ABSTRACT

Disclosed embodiments are generally related to semiconductor device inspection. One such embodiment involves positioning a detector at a distance from a surface of the semiconductor device being inspected and applying an energy to the semiconductor device. In the disclosed embodiment, the detector receives back-scattered energy resulting from applying the energy to the semiconductor device and the resultant back-scattered energy is processed and analyzed to determine whether defects are beneath the surface of the semiconductor device. The magnitude of the applied energy and the distance between the detector and the surface of the semiconductor device are selected so as to allow back-scattered electrons returned from applying to be effectively received by the detector.

### BACKGROUND

The present disclosure relates generally to semiconductor structures and/or devices, fabricating semiconductor structures and/or devices, and more specifically, relates to inspecting fabricated and/or partially fabricated semiconductor structures and/or devices.

In the continuously evolving semiconductor field, semiconductor manufacturers generally compete to bring to market semiconductor devices, such as memory devices, having both greater storage capacity and smaller physical size. Semiconductor device manufacturers attempt to achieve one or more of these goals by making dimensionally smaller each of the patterns in the series of patterns formed on photoresist masks, photoresist layers, and corresponding fabricated semiconductor structures and devices. Alternatively or in addition, attempts include forming the patterns on the mask, the photoresist layers, and corresponding fabricated semiconductor structures and devices to be dimensionally smaller and/or closer to one another so as to increase the density of patterns and/or structures formed in and/or on the resultant semiconductor device.

### BRIEF SUMMARY

Recent developments have enabled the shrinking of critical dimensions of semiconductor structures and devices. However, it is recognized in the present disclosure that one or more problems are encountered in the consistent and reliable commercial fabrication of semiconductor structures and devices. For example, difficulties are encountered in achieving improved performance and increased reliability resulting from, among other things, inconsistencies formed in, on, and/or under the surface of semiconductor structures and devices. Such inconsistencies may include, without limitation, surface defects, pits, voids, oxide bridges, partial breaks, and complete or total breaks (openings), including those formed in or on one or more layers under the surface of the semiconductor structures and devices.

Present example embodiments relate generally to methods, systems, and devices for inspecting (or examining, detecting, or testing) fabricated and/or partially fabricated semiconductor structures and/or devices. Example embodiments also include determining a presence of one or more inconsistencies in, on, and/or buried under a surface of the semiconductor structures and/or devices being inspected. Inconsistencies may include designed features or structures, such as copper interconnects, and/or defects in, on, or buried under the surface of the semiconductor structures and/or devices (generally and without limitation collectively referred to for convenience herein as “inconsistencies” or “defects.”)

In an example embodiment, a method for inspecting a semiconductor device (or structure, referred to interchangeably as a semiconductor device) may comprise positioning a detector at a first distance from a surface of the semiconductor device being inspected. The method may further comprise applying, from an energy source (such as an electron beam source, or e-beam source), an energy (such as an electron beam, or e-beam) of a first magnitude to the semiconductor device being inspected. The method may further comprise receiving, by the positioned detector, a resultant energy of a second magnitude returned from the applying. The resultant energy may comprise back-scattered electrons. The resultant energy may also comprise secondary electrons. The method may further comprise processing the received resultant energy. The method may further comprise determining a presence of an inconsistency buried under the surface of the semiconductor device being inspected based on the processing of the received resultant energy. At least one of the first magnitude of the applied energy and the first distance of the detector may be selected so as to allow, among other things, back-scattered electrons returned from applying of the energy from the energy source to be received by the detector.

In another example embodiment, a method for inspecting a semiconductor device comprises positioning a detector at a first distance from a surface of the semiconductor device being inspected. The method may further comprise applying, from an energy source (such as an electron beam source, or e-beam source), an energy (such as an electron beam, or e-beam) of a first magnitude to the semiconductor device being inspected. The method may further comprise receiving, by the positioned detector, a resultant energy of a second magnitude returned from the applying. The resultant energy may comprise back-scattered electrons. The resultant energy may also comprise secondary electrons. The method may further comprise processing the received resultant energy. The method may further comprise determining a presence of an inconsistency buried under the surface of the semiconductor device based on the processing. A yield of the received resultant energy of less than or equal to about 0.18 may be achieved, the yield being a ratio of the second magnitude (of the received resultant energy returned from the semiconductor device being inspected) to the first magnitude (of the applied energy from the energy source).

### BRIEF DESCRIPTION OF THE DRAWINGS

For a more complete understanding of the present disclosure, example embodiments, and their advantages, reference is now made to the following description taken in conjunction with the accompanying drawings, in which like reference numbers indicate like features, and:

FIG. 1A is an example illustration of an example method of inspecting a semiconductor device;

FIG. 1B is an example illustration of another example method of inspecting a semiconductor device;

FIG. 2 is an example embodiment of method of inspecting a semiconductor device;

FIG. 3 is an example illustration of an example embodiment of a device and system for inspecting a semiconductor device;

FIG. 4 is an example illustration of the yield of a resultant energy and the energy applied by an energy source according to example embodiments disclosed in the present disclosure;

FIG. 5 is an example illustration depicting inconsistencies detected using example embodiments; and

FIG. 6 is another example illustration depicting inconsistencies detected using example embodiments.

Although similar reference numbers may be used to refer to similar elements for convenience, it can be appreciated that each of the various example embodiments may be considered to be distinct variations.

Example embodiments will now be described with reference to the accompanying drawings, which form a part of the present disclosure, and which illustrate example embodiments which may be practiced. As used in the present disclosure and the appended claims, the terms “example embodiment,” “exemplary embodiment,” and “present embodiment” do not necessarily refer to a single embodiment, although they may, and various example embodiments may be readily combined and/or interchanged without departing from the scope or spirit of example embodiments. Furthermore, the terminology as used in the present disclosure and the appended claims is for the purpose of describing example embodiments only and is not intended to be limitations. In this respect, as used in the present disclosure and the appended claims, the term “in” may include “in” and “on,” and the terms “a,” “an” and “the” may include singular and plural references. Furthermore, as used in the present disclosure and the appended claims, the term “by” may also mean “from,” depending on the context. Furthermore, as used in the present disclosure and the appended claims, the term “if” may also mean “when” or “upon,” depending on the context. Furthermore, as used in the present disclosure and the appended claims, the term “under” may also mean “below,” “in,” or “within,” depending on the context. Furthermore, as used in the present disclosure and the appended claims, the words “and/or” may refer to and encompass any and all possible combinations of one or more of the associated listed items.

### DETAILED DESCRIPTION

It is recognized in the present disclosure that one or more problems may be encountered in the fabrication of semiconductor devices, including difficulties in achieving improved performance and/or increased reliability, and such problems may be caused by defects on and/or buried under a surface of semiconductor devices. Although defects on a surface (surface defects) of semiconductor devices may be readily inspected, current methods and devices have not been effective in inspecting, detecting, and determining a location of internal defects formed under a surface of semiconductor devices. Surface defects formed on fabricated or partially fabricated semiconductor devices have conventionally been inspected and identified using various inspection tools, such as inspection tools made by KLA-Tencor, Applied Material, HMI, and other manufacturers. It is recognized in the present disclosure that such conventional methods and devices, however, are generally ineffective in detecting interior defects formed buried under the surface of semiconductor devices.

Present example embodiments relate generally to methods, logic, systems, and devices for inspecting (or examining, detecting, or testing) fabricated and/or partially fabricated semiconductor devices. The use of the described example embodiments enable testers/inspectors to, among other things, improve the performance of their products and ensure their products are reliable and meet their product specifications. Example embodiments enable testers/inspectors to achieve this by determining if any inconsistencies are present on and/or buried under a surface of the semiconductor device. If such defects are found, example embodiments may enable testers/inspectors to make a decision on whether or not to accept or reject the semiconductor device during the inspection/testing phase by determining the severity of the found inconsistencies. Example embodiments also enable testers/inspectors to determine the location of the inconsistencies on and/or buried under the surface of fabricated and/or partially fabricated semiconductor devices.

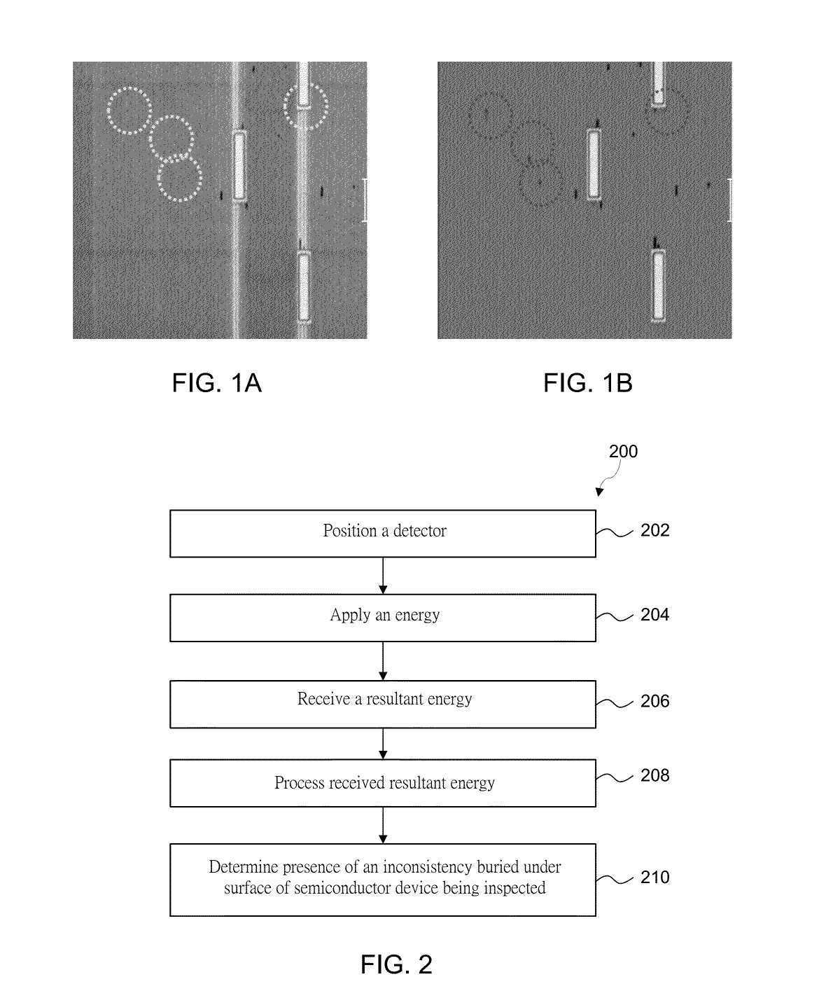

FIG. 1A illustrates an example result of applying an electron beam of magnitude 3,000 eV to a semiconductor device. A detector is operable to receive a resulting energy of secondary electrons returned from the semiconductor device caused by the applying of the electron beam, the detector positioned at a distance of about 10-30 mm from the surface of the semiconductor device. As illustrated in FIG. 1A, the presence of some inconsistencies, including designed structures on the surface of the semiconductor device and surface defects, may be identified and determined based on processing of the received secondary electrons. However, certain inconsistencies, including internal defects formed buried under the surface of the semiconductor device, may not be detectable using such methods. For example, internal defects formed buried at a depth of about 100 nm under the surface of the semiconductor device may not be detectable and determinable by such methods.

FIG. 1B illustrates an example result of an example embodiment of a method performed on the semiconductor device inspected in FIG. 1A above. As shown in FIG. 1B, the presence of inconsistencies, such as internal defects (as detected and shown by the dashed circle in FIG. 1B, but not detected and absent in the dashed circle in FIG. 1A), buried under the surface of the semiconductor device, which were not determinable using the methods described for FIG. 1A, may be detected and determined. Internal defects determinable using example embodiments may include pits (or holes or cavities or bores), partial breaks, complete breaks (or openings), oxide bridges (which may include pits, partial breaks, and/or complete breaks filled or partially filled with insulating material from the insulating layer(s)), and inconsistencies at the border between the layers.

Example embodiments of methods 200, such as the method applied in FIG. 1B, for inspecting a semiconductor device for a presence of one or more inconsistencies on and/or buried under a surface of the semiconductor device may include one or more of the following actions: positioning a detector at a distance above a surface of the semiconductor device being inspected (e.g., action 202), applying an energy (such as an electron beam, or e-beam) of a first magnitude from an energy source (such as an electron beam source, or e-beam source) to the semiconductor device being inspected (e.g., action 204), receiving a resultant energy (such as secondary electrons and/or back-scattered electrons) of a second magnitude returned from the semiconductor device being inspected after the applying of the energy from the energy source to the semiconductor device (e.g., action 206), processing the received resultant energy (e.g., action 208), and determining a presence of one or more inconsistencies, such as an internal and/or surface defect, on and/or buried under the surface of the semiconductor device being inspected (e.g., action 210).

Example embodiments of methods 200 and systems/devices 300 for use in inspecting a semiconductor device for a presence of one or more inconsistencies on and/or buried under a surface of a semiconductor device will now be described with reference to at least FIGS. 1 to 6.

(1) Positioning a Detector Above a Surface of the Semiconductor Device being Inspected (e.g., Action 202).

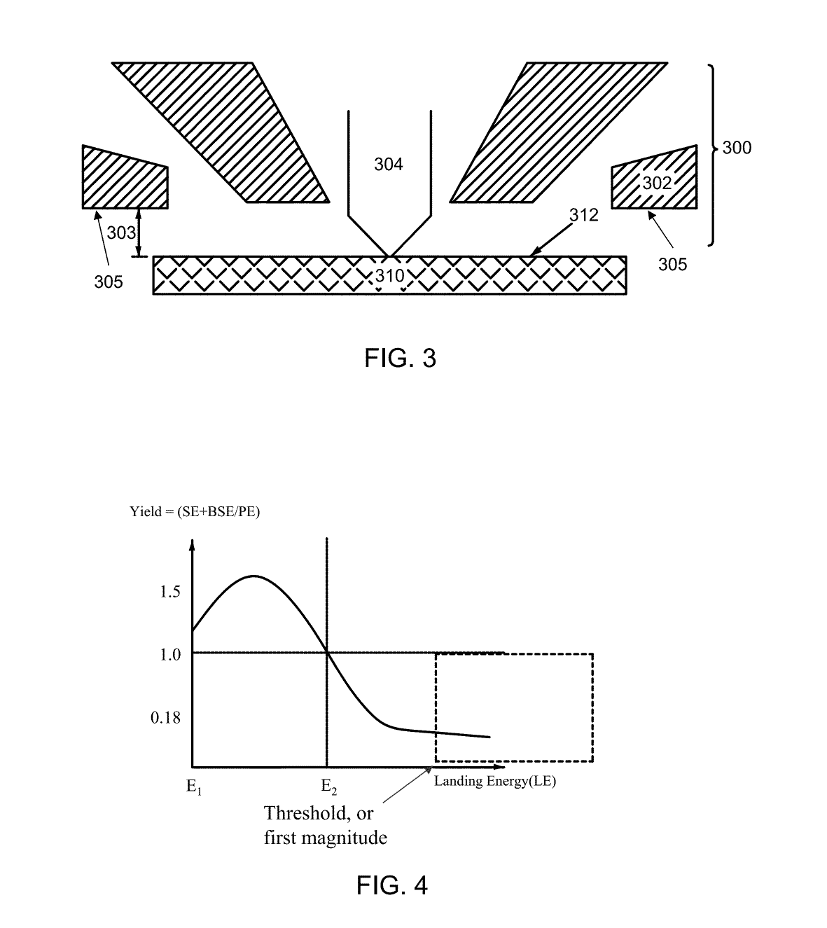

As illustrated in the method 200 of FIG. 2 and the device/system 300 of FIG. 3, an example embodiment of a method 200 of inspecting a semiconductor device 310 using an inspection device/system 300 for a presence of one or more inconsistencies buried under a surface 312 of the semiconductor device 310 may include positioning (e.g., action 202) a detector 302 at a distance 303 from the surface 312 of the semiconductor device 310. The distance 303 of the detector 302 from the surface 312 may be selectable to be less than or equal to about 1 mm in example embodiments. In example embodiments, the distance 303 of the detector 302 from the surface 312 may be selectable to be a value between about 0.1 mm to about 0.75 mm. In example embodiments, the distance 303 of the detector 302 from the surface 312 may be selectable based on, among other things, a desired inspection depth (or “penetration depth”) under the surface 312 of the semiconductor device 310 (to be further described in action 208 below), the composition(s) and/or thickness(es) of the semiconductor device being inspected, the magnitude of energy applied by the energy source 304 (to be further described in action 204 below), and/or the resolution of the energy applied from the energy source 304. It is to be understood in the present disclosure that the surface 305 of the detector 302 facing the surface 312 of the semiconductor device 310 for receiving and detecting the resultant energy returned from the semiconductor device 310 may be of any shape, form, and/or size, such as a ring, without departing from the teachings of the present disclosure.

(2) Applying Energy from an Energy Source to the Semiconductor Device being Inspected (e.g., Action 204).

An energy source 304 (such as an electron beam source, or e-beam source) may be positioned above the surface 312 of the semiconductor device 310 and an energy (such as an electron beam, or e-beam) of a first magnitude may be applied (e.g., action 204) from the energy source 304 to the semiconductor device 310. It is to be understood in the present disclosure that the application of the energy (e.g., action 204) and the positioning (e.g., action 202) of the detector 302 may be performed in such a way that a resultant energy (including back-scattered electrons and secondary electrons), which is returned from the semiconductor device 310 being inspected after the applying of the energy, is sufficiently received by the detector 302. It is also to be understood in the present disclosure that the energy source 304 may be attached to, connected to, in communication with, and/or integrated with the detector 302 without departing from the teachings of the present disclosure.

To achieve a sufficient penetration depth under the surface of a semiconductor device being inspected, the first magnitude of the energy applied by the energy source 304 may be selectable to be greater than or equal to about 6,000 eV in example embodiments. In example embodiments, the first magnitude of the energy applied by the energy source 304 may be selectable to be greater than about 9,000 eV. In example embodiments, the first magnitude of the energy applied by the energy source 304 may be selectable to be a value between about 6,000 eV and 50,000 eV. In example embodiments, the first magnitude of the energy applied by the energy source 304 may be selectable based on, among other things, the distance 303 of the detector 302 selected, the composition(s) and/or thickness(es) of the semiconductor device 310 being inspected, the desired inspection depth under the surface 312 of the semiconductor device 310 (to be further described in action 208 below), the resultant energy returned from the semiconductor device 310 (such as the magnitude of the back-scattered electrons returned from the semiconductor device 310), and/or the resolution of the energy applied by the energy source 304. For example, an electron beam of magnitude 9,500 eV was selected and applied to a semiconductor device having a composition of silicon carbon nitride (35 nm thickness) and copper (100 nm thickness), and the applied electron beam was operable to achieve a penetration depth of at least 100 nm below the surface of the semiconductor device.

(3) Receiving a Resultant Energy Returned from the Semiconductor Device being Inspected after Applying the Energy from the Energy Source (e.g., Action 206).

After applying energy of a first magnitude (e.g., action 204) from the energy source 304 to the semiconductor device 310 being inspected, a resultant energy may be returned from the semiconductor device 310 and received and detected (e.g., action 206) by the detector 302. Specifically, after the energy of a first magnitude is applied (e.g., action 204) from the energy source 304 to the semiconductor device 310, a resultant energy comprising back-scattered electrons (and secondary electrons) may be returned from the semiconductor device 310 and received and detected (e.g., action 206) by the detector 302.

In example embodiments, the aforementioned resultant energy, including the back-scattered electrons, may be received (e.g., action 206) by the detector 302 for further processing (e.g., action 208) by a processor (not shown) and/or the inspection device 300. It is to be understood in the present disclosure that the positioning (e.g., action 202) of the detector 302 with respect to the energy source 304 may be performed in such a way that the resultant energy returned from the applying (e.g., action 204) of the energy by the energy source 304 can be sufficiently received (e.g., action 206) by the detector 302.

(4) Processing the Received Resultant Energy (e.g., Action 208).

Upon receiving (e.g., action 206) the resultant energy by the detector 302, the resultant energy may be processed (e.g., action 208). In an example embodiment, the processing (e.g., action 208) may be performed by a processor (not shown) and/or the inspection device 300. The processing (e.g., action 208) may comprise analyzing and/or measuring back-scattered electrons returned from the semiconductor device for further use in determining a presence of internal defects buried under the surface 312 of the semiconductor device 310. In example embodiments, the processing (e.g., action 208) may include determining a magnitude (in eV) of the received back-scattered electrons. The processing (e.g., action 208) may further comprise analyzing and/or measuring the secondary electrons returned from the semiconductor device for further use in determining a presence of surface defects on and/or under the surface 312 of the semiconductor device 310. In example embodiments, the processing (e.g., action 208) may include determining a magnitude (in eV) of the received secondary electrons. It is to be understood in the present disclosure that the processing (e.g., action 208) may perform the analyzing and/or measuring of the back-scattered electrons and the secondary electrons together or separately.

Upon receiving the resultant energy by the detector 302, a yield of the resultant energy may be determined. In example embodiments, the yield may be determined by obtaining a ratio of the magnitude of the resultant energy to the magnitude of the energy applied by the energy source 304. In example embodiments, the yield may be determined by obtaining a ratio of the sum of the magnitude of the received secondary electrons and the magnitude of the received back-scattered electrons to the magnitude of the applied primary electrons (i.e., the energy applied by the energy source 304). In example embodiments, the yield may be determined by a processor (not shown) and/or the inspection device 300, as follows:

yield=(magnitude of resultant energy)/(magnitude of energy applied by the energy source); and/or

yield=[(magnitude of the secondary electrons)+(magnitude of the back-scattered electrons)]/(magnitude of the primary electrons).

FIG. 4 illustrates an example embodiment of the yield of the resultant energy (vertical axis) and the energy applied by the energy source 304 (horizontal axis) for a detector 302 positioned at a distance of 0.75 mm above the surface 312 of a semiconductor device 310 having a composition of silicon carbon nitride (35 nm thickness) and copper (100 nm thickness). As illustrated in FIG. 4, example embodiments are operable to apply an energy (or landing energy (LE)) of greater than or equal to a threshold value, as described above for action 204 and depicted by the dotted section in FIG. 4. In example embodiments, the threshold value of the applied energy may be greater or equal to about 6,000 eV.

The energy applied by the energy source 304 may not achieve a sufficient penetration depth in the semiconductor device 310, such as in situations wherein the first magnitude of the applied energy is too low (such as below a threshold value of 6,000 eV) and/or the distance/position of the detector is too high (such as greater than a threshold value of 1 mm). As another example, the yield of the resultant energy may be too high (such as greater than a threshold value of 0.18). In such situations, it may be possible that certain internal defects that are buried more deeper below the surface 312 of the semiconductor device 310 may not be detected. For example, the energy applied by the energy source 304 may not achieve a sufficient penetration depth below the surface 312 of the semiconductor device 310 being inspected. In example embodiments, the threshold value of the yield of the resultant energy may be about 0.18 or less, the threshold value of the first magnitude of the applied energy may be about 6,000 eV or more, and the threshold value of the distance/position 303 of the detector 302 may be 1 mm or less. In example embodiments, the threshold value of the yield of the resultant energy may be about 0.16 or less, the threshold value of the first magnitude of the applied energy may be about 9,000 eV or more, and the threshold value of the distance/position 303 of the detector 302 may be 0.75 mm or less.

An increase in the penetration depth (and/or reduction in the yield) may be achievable in one or more of a plurality of ways. In an example embodiment, the yield may be reduced by selecting (or increasing) the magnitude of the energy applied by the energy source 304 to be a greater value, such as a value greater than or equal to about 9,000 eV. In example embodiments, the selected magnitude of the energy applied by the energy source 304 may be operable to penetrate a depth of at least 100 nm under the surface 312 of the semiconductor device 310 being inspected (and the yield may be reduced to a value of less than or equal to about 0.18). In example embodiments, the selected magnitude of the energy applied by the energy source 304 may be operable to determine a presence of one or more inconsistencies buried under the surface 312 of the semiconductor device 310 at a depth of at least 100 nm under the surface 312 of the semiconductor device 310. The penetration depth may also be increased (yield reduced) by selecting (or decreasing) the distance/position 303 of the detector 302 to be closer to the surface 312 of the semiconductor device 310, such as positioning the detector 302 to be at a distance of less than or equal to about 0.75 mm from the surface 312 of the semiconductor device 310. In an example embodiment, the penetration depth may also be increased (yield reduced) by selecting (or increasing) the magnitude of the energy applied by the energy source 304 to be a greater value, such as greater than or equal to about 9,000 eV, and selecting (or reducing) the distance/position 303 of the detector 302 to be a smaller value, such as less than or equal to about 0.75 mm from the surface 312 of the semiconductor device 310.

In an example embodiment, the penetration depth under the surface 312 of the semiconductor device 310 being inspected, the yield of the resultant energy, the magnitude of the energy applied by the energy source 304 to the semiconductor device 310, the distance/position 303 of the detector 302 (i.e., the distance between the detector 302 and the surface 312 of the semiconductor device 310), and/or the resultant energy (including the back-scattered electrons) returned from the semiconductor device 310 may be selected based on, among other things, a desired inspection depth (or penetration depth) under the surface 312 of the semiconductor device 310 being inspected, the composition(s) and/or thickness(es) of the semiconductor device 310 being inspected, the magnitude of the energy applied by the energy source 304 to the semiconductor device 310, the distance/position 303 of the detector 302, and/or the resolution of the energy applied from the energy source 304.

(5) Determining a Presence of an Inconsistency Buried Under the Surface of the Semiconductor Device (e.g., Action 210).

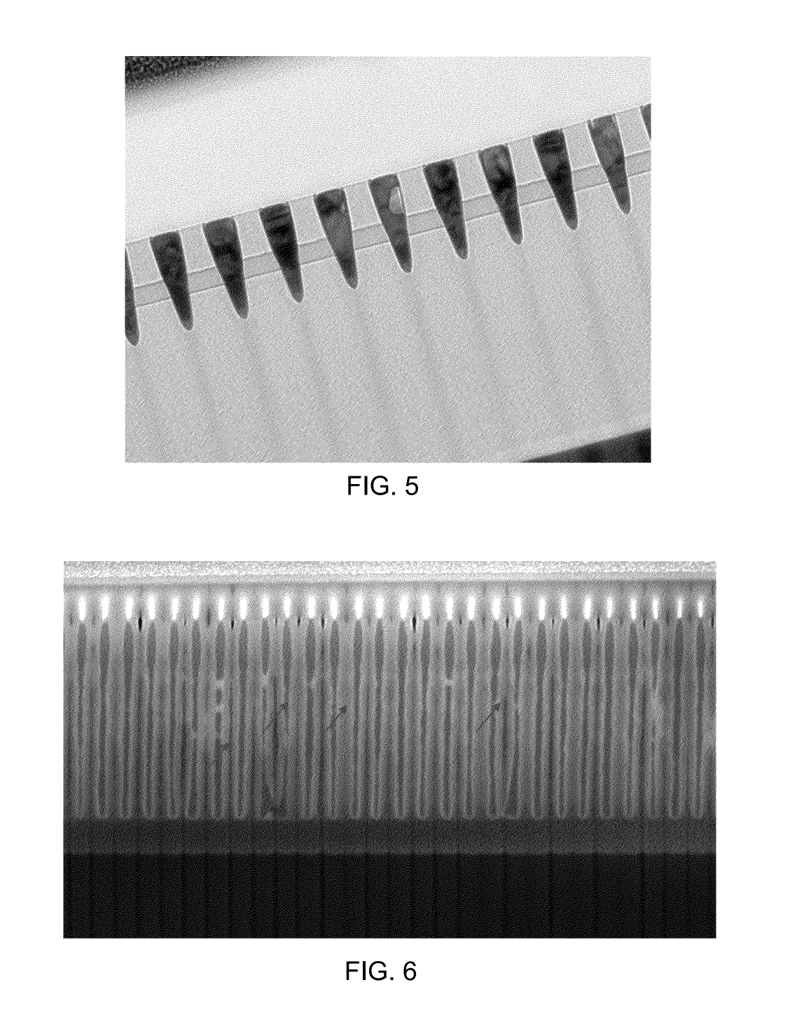

The processing (e.g., action 208) of the received resultant energy (including the back-scattered electrons and/or the secondary electrons) returned from the semiconductor device (after applying the energy from the energy source) may enable the inspection device 300 (and/or processor (not shown), external or associated imaging/capturing device, and/or external or associated printing device) to, either directly or indirectly, provide imaging results of the processing (e.g., action 208). An example imaging result is illustrated in FIG. 1B. FIG. 5 also illustrates imaging results showing buried voids in a copper interconnect. FIG. 6 illustrates imaging results showing bridges formed in a 3-dimensional NAND device.

Examples of Methods of and Devices for Inspecting a Semiconductor Device.

As an example, a method for inspecting a semiconductor device may comprise positioning a detector at a first distance from a surface of the semiconductor device being inspected. The method may further comprise applying, from an energy source (such as an electron beam source), an energy (such as an electron beam, or e-beam) of a first magnitude to the semiconductor device being inspected. The method may further comprise receiving, by the positioned detector, a resultant energy of a second magnitude returned from the applying. The resultant energy may comprise back-scattered electrons. The method may further comprise processing the received resultant energy. The method may further comprise determining a presence of an inconsistency buried under the surface of the semiconductor device being inspected based on the processing of the received resultant energy. At least one of the first magnitude of the applied energy and the first distance of the detector may be selected so as to allow back-scattered electrons returned from applying of the energy from the energy source to be received by the detector. The presence of the inconsistency buried under the surface of the semiconductor device may be determined based on at least the processing of the back-scattered electrons received by the detector. The first distance of the detector may be less than about 1 mm. The first distance of the detector may be between about 0.1 mm to 0.75 mm. The first magnitude of the applied energy may be greater than or equal to about 6000 eV. The first magnitude of the applied energy may be between about 6000 eV to 50,000 eV. The processing may be operable to determine the presence of inconsistencies buried under the surface of the semiconductor device at a depth of at least 100 nm under the surface of the semiconductor device. The first magnitude of the energy may be operable to penetrate a depth of at least 100 nm under the surface of the semiconductor device. The first magnitude may be based on a desired inspection depth under the surface of the semiconductor device. The first distance may also be selected based on a desired inspection depth under the surface of the semiconductor device. The first magnitude may also be selected based on a composition of the semiconductor device. The first distance may also be selected based on a composition of the semiconductor device.

As another example, a method for inspecting a semiconductor device may comprise positioning a detector at a first distance from a surface of the semiconductor device being inspected. The method may further comprise applying, from an energy source (such as an electron beam source), an energy (such as an electron beam, or e-beam) of a first magnitude to the semiconductor device being inspected. The method may further comprise receiving, by the positioned detector, a resultant energy of a second magnitude returned from the applying. The resultant energy may comprise back-scattered electrons. The method may further comprise processing the received resultant energy. The method may further comprise determining a presence of an inconsistency buried under the surface of the semiconductor device based on the processing. A yield of the received resultant energy of less than or equal to about 0.18 may be achieved, the yield being a ratio of the second magnitude (of the received resultant energy returned from the semiconductor device being inspected) to the first magnitude (of the applied energy from the energy source). The resultant energy may comprise secondary electrons and back-scattered electrons, and the second magnitude may be a sum of the magnitude of the secondary electrons received by the detector and the magnitude of the back-scattered electrons received by the detector. The presence of the inconsistency buried under the surface of the semiconductor device may be determined based on at least the back-scattered electrons received by the detector. The yield of less than or equal to about 0.18 may be achieved based on the selecting of the first magnitude of the energy from the energy source. The yield of less than or equal to about 0.18 may be achieved based on the selecting of the first distance of the detector. The first magnitude of the applied energy from the energy source may be adjusted to achieve a yield of less than or equal to about 0.18 when the yield is greater than about 0.18. The first distance of the detector may be adjusted to achieve a yield of less than or equal to about 0.18 when the yield is greater than about 0.18. The first distance of the detector may be less than about 1 mm. The first distance of the detector may be between about 0.1 mm to 0.75 mm. The first magnitude of the applied energy may be greater than or equal to about 6000 eV. The first magnitude of the applied energy may be between about 6000 eV to 50,000 eV. The selected first magnitude may be operable to determine the presence of inconsistencies buried under the surface of the semiconductor device at a depth of at least 100 nm under the surface of the semiconductor device. The first magnitude of the electron beam that achieves a yield of less than or equal to about 0.18 may be operable to penetrate a depth of at least 100 nm under the surface of the semiconductor device. The first magnitude may be selected based on a desired inspection depth under the surface of the semiconductor device. The first distance may be selected based on a desired inspection depth under the surface of the semiconductor device. The first magnitude may be selected based on a composition of the semiconductor device. The first distance may be selected based on a composition of the semiconductor device.

Accordingly, in applying example embodiments for the inspecting of a semiconductor device, including those described above and in the present disclosure, example embodiments may be operable to determine a presence of one or more inconsistencies buried under (and/or formed on) a surface of a semiconductor device being inspected, and may enable testers/inspectors applying and/or practicing example embodiments to make a decision on whether or not to accept or reject the semiconductor device during the inspection phase by determining the severity of the found defects. Example embodiments also enable a determination of the location(s) of inconsistencies, including internal defects, found buried under the surface of the semiconductor device being inspected.

While various embodiments in accordance with the disclosed principles have been described above, it should be understood that they have been presented by way of example only, and are not limiting. Thus, the breadth and scope of the example embodiments described in the present disclosure should not be limited by any of the above-described exemplary embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

Example embodiments of the methods, devices, and systems described in this description may simultaneously perform the inspection of one, some, or all parts of a surface of a semiconductor device. For example, an energy source and detector pair (or a single inspection device comprising an energy source and a detector) may be applied to a surface of a semiconductor device, such as by scanning (applying (e.g., action 204) and receiving (e.g., action 206)) the semiconductor device being inspected in a raster scan pattern (or other pattern). As another example, more than one energy source and detector pair (or one or more inspection devices comprising one or more than one energy source and/or one or more than one detector) may be applied to one or more different parts of the semiconductor device being inspected, and the processing results (processing (e.g., action 208) and determining (e.g., action 210)) of the scanning may be later combined together for use in example embodiments of determining (e.g., action 210) a presence of an inconsistency in the semiconductor device being inspected. It is to be understood in the present disclosure that example embodiments may be operable to detect more than one inconsistency and/or more than one surface defect in and/or on the semiconductor device.

“Inconsistencies” or “defects,” including internal defects, formed in and/or on material(s), layer(s), and/or between materials and/or layers may include openings, bores, gaps, voids, cracks, holes, bubbles, bumps, and the like, comprising air, other gases, and/or compositions other than the material and/or compositions of its surrounding material and/or layer(s), and/or a mixture thereof. Furthermore, although the present disclosure describes example embodiments for addressing inconsistencies or defects, the claimed approaches described in the present disclosure may also be beneficially applicable to address and/or improve other performance-related problems and/or issues, including formation, shifting, changing in size, changing in shape, changing in composition, combining, dividing, and/or migrating of other types of imperfections in the semiconductor fabrication process.

Semiconductor structures and/or devices may include any internal structure of a semiconductor device or structure, including floating gate layers/structures, control gate layers/structures, other structures in charge-trap type devices, charge storage structures such as silicon-oxide-nitride-oxide-silicon (SONOS), and/or bandgap engineered silicon-oxide-nitride-oxide-silicon (BE-SONOS) structures comprising a tunneling dielectric layer, a trapping layer, and a blocking oxide layer.

Example embodiments may also be operable to report, such as by a processor (not shown) and/or the inspection device 300, and/or to display, such as by a graphical display (not shown) or printed on a physical medium (not shown), the processing and determining results of the inspection, including determining the presence of inconsistencies, identifying the severity of the inconsistencies, and identifying a location of the inconsistencies. Such reporting may include sending the results of the inspection for displaying on a graphical display (not shown), sending the results of the inspection via electronic communications (such as via e-mail and/or other ways) to responsible personnel, databases, and/or other systems, and/or sending the results of the inspection for printing the results. The previously described action of sending the results of the inspection may be performable via communications, either directly through wired and/or wireless communication or indirectly, from the processor. Example embodiments may also be operable to provide, such as by the processor, results of the inspection for one or more manual and/or automatic adjustments to the fabrication process so as to prevent future occurrences of inconsistencies.

Although the example embodiments described above and in the present disclosure are generally described for inspecting semiconductor devices, example embodiments will be equally applicable to inspecting fabricated and/or partially fabricated semiconductor structures and/or devices, or the like. Semiconductor devices and structures that may be inspected using example embodiments disclosed in the present disclosure include, but are not limited to, 3-dimensional IC devices (detecting internal pre-layer defects in, on, and/or nearby word lines and/or bit lines), non-visual defects, buried voids and/or other defects in, on, and/or nearby conductive structures such as copper interconnects, and the like.

Various terms used in the present disclosure have special meanings within the present technical field. Whether a particular term should be construed as such a “term of art” depends on the context in which that term is used. “Connected to,” “in communication with,” “associated with,” or other similar terms should generally be construed broadly to include situations both where communications and connections are direct between referenced elements or through one or more intermediaries between the referenced elements. These and other terms are to be construed in light of the context in which they are used in the present disclosure and as one of ordinary skill in the art would understand those terms in the disclosed context. The above definitions are not exclusive of other meanings that might be imparted to those terms based on the disclosed context.

Words of comparison, measurement, and timing such as “at the time,” “equivalent,” “during,” “complete,” and the like should be understood to mean “substantially at the time,” “substantially equivalent,” “substantially during,” “substantially complete,” etc., where “substantially” means that such comparisons, measurements, and timings are practicable to accomplish the implicitly or expressly stated desired result. In the context of the present application, such approximate measurements include approximate dimensional measurements of semiconductor devices, approximate yields, approximate distances of detector positioning, and approximate measured energy levels.

Additionally, the section headings in the present disclosure are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” section shall not be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings in the present disclosure.

1. A method of inspecting a semiconductor device, the method comprising:
positioning a detector at a first distance from a surface of the semiconductor device;
applying, from an energy source, an energy of a first magnitude to the semiconductor device;
receiving, by the detector, a resultant energy of a second magnitude returned from the applying;
processing the received resultant energy; and
determining a presence of an inconsistency buried under the surface of the semiconductor device based on the processing;
wherein at least one of the first magnitude and the first distance is selected so as to allow back-scattered electrons returned from the applying to be received by the detector.

2. The method of claim 1, wherein the energy applied by the energy source is an electron beam and the resultant energy comprises back-scattered electrons and secondary electrons.

3. The method of claim 1, wherein the presence of the inconsistency buried under the surface of the semiconductor device is determined based on at least the processing of the back-scattered electrons received by the detector.

4. The method of claim 1, wherein a yield of less than or equal to about 0.18 is achieved, the yield being a ratio of the second magnitude to the first magnitude.

5. The method of claim 1, wherein the first distance of the detector is less than or equal to about 1 mm.

6. The method of claim 1, wherein the first distance of the detector is a value between about 0.1 mm to 0.75 mm.

7. The method of claim 1, wherein the first magnitude of the applied energy is greater than or equal to about 6000 eV.

8. The method of claim 1, wherein the first magnitude of the applied energy is a value between about 6000 eV to 50,000 eV.

9. The method of claim 1, wherein the processing is operable to determine the presence of inconsistencies buried under the surface of the semiconductor device at a depth of at least about 100 nm under the surface of the semiconductor device.

10. The method of claim 1, wherein the first magnitude of the energy is operable to penetrate a depth of at least about 100 nm under the surface of the semiconductor device.

11. The method of claim 1, further comprising selecting the first magnitude based on a desired inspection depth under the surface of the semiconductor device.

12. The method of claim 1, further comprising selecting the first distance based on a desired inspection depth under the surface of the semiconductor device.

13. The method of claim 1, further comprising selecting the first magnitude based on a composition of the semiconductor device.

14. The method of claim 1, further comprising selecting the first distance based on a composition of the semiconductor device.

15. A method of inspecting a semiconductor device, the method comprising:
positioning a detector at a first distance from a surface of the semiconductor device;
applying, from an energy source, an energy of a first magnitude to the semiconductor device;
receiving, by the detector, a resultant energy of a second magnitude returned from the applying;
processing the received resultant energy; and
determining a presence of an inconsistency buried under the surface of the semiconductor device based on the processing;
wherein a yield of less than or equal to about 0.18 is achieved, the yield being a ratio of the second magnitude to the first magnitude.

16. The method of claim 15, wherein the resultant energy comprises secondary electrons and back-scattered electrons, and wherein the second magnitude is a sum of the magnitude of the secondary electrons received by the detector and the magnitude of the back-scattered electrons received by the detector.

17. The method of claim 16, wherein the presence of the inconsistency buried under the surface of the semiconductor device is determined based on at least the back-scattered electrons received by the detector.

18. The method of claim 16, wherein at least one of the first magnitude and the first distance is selected so as to allow back-scattered electrons returned from applying to be received by the detector.

19. The method of claim 15, wherein the yield of less than or equal to about 0.18 is achieved based on the selecting of the first magnitude of the energy from the energy source.

20. The method of claim 15, wherein the yield of less than or equal to about 0.18 is achieved based on the selecting of the first distance of the detector.

21. The method of claim 15, further comprising adjusting the first magnitude of the applied energy from the energy source to achieve a yield of less than or equal to about 0.18 when the yield is greater than about 0.18.

22. The method of claim 15, further comprising adjusting the first distance of the detector to achieve a yield of less than or equal to about 0.18 when the yield is greater than about 0.18.

23. The method of claim 15, wherein the first distance of the detector is less than or equal to about 1 mm.

24. The method of claim 15, wherein the first distance of the detector is a value between about 0.1 mm to 0.75 mm.

25. The method of claim 15, wherein the first magnitude of the applied energy is greater than or equal to about 6000 eV.

26. The method of claim 15, wherein the first magnitude of the applied energy is a value between about 6000 eV to 50,000 eV.

27. The method of claim 15, wherein the selected first magnitude is operable to determine the presence of inconsistencies buried under the surface of the semiconductor device at a depth of at least about 100 nm under the surface of the semiconductor device.

28. The method of claim 15, wherein the first magnitude of the electron beam that achieves the yield of less than or equal to about 0.18 is operable to penetrate a depth of at least about 100 nm under the surface of the semiconductor device.

29. The method of claim 15, further comprising selecting the first magnitude based on a desired inspection depth under the surface of the semiconductor device.

30. The method of claim 15, further comprising selecting the first distance based on a desired inspection depth under the surface of the semiconductor device.

31. The method of claim 15, further comprising selecting the first magnitude based on a composition of the semiconductor device.

32. The method of claim 15, further comprising selecting the first distance based on a composition of the semiconductor device.
